(19) United States
(12) Patent Application Publication
(10) Pub. No.: US 2026/0323990 A1
(43) Pub. Date: Oct. 15, 2026

(54) SWITCHING ELEMENT AND METHOD FOR MANUFACTURING THE SAME

(71) Applicants: DENSO CORPORATION, Kariya-shi (JP); TOYOTA JIDOSHA KABUSHIKI KAISHA, Toyota-shi (JP); MIRISE Technologies Corporation, Nisshin-shi (JP)

(72) Inventors: Tomofumi NIIBAYASHI, Nisshin-shi (JP); Jun SAITO, Nisshin-shi (JP)

(21) Appl. No.: 19/464,979

(22) Filed: Jan. 30, 2026

(30) Foreign Application Priority Data
Feb. 6, 2025 (JP) 2025-018537

(51) Int. Cl. H10D 30/66; H10D 30/01; H10D 62/00; H10D 62/13; H10D 64/01; H10D 64/27

(52) U.S. Cl. CPC H10D 30/668; H10D 30/0297; H10D 62/051; H10D 62/154; H10D 64/027; H10D 64/513

(57) ABSTRACT

A switching element includes p-type electric field relaxation regions, n-type spacing regions, super junction p-type regions, and super junction n-type regions. The field relaxation regions extend in a first direction. The n-type spacing regions are disposed in spaces between the electric field relaxation regions. The super junction p-type regions are disposed below the electric field relaxation regions. The super junction p-type regions extend in a second direction. The super junction n-type regions are disposed in spaces between the super junction p-type regions. The super junction n-type regions each include a low charge quantity region that is in contact with the electric field relaxation regions and the n-type spacing regions from below, and a high charge quantity region that is in contact with the low charge quantity region from below and has an n-type charge quantity higher than that in the low charge quantity region.

### CROSS REFERENCE TO RELATED APPLICATION

The present application claims the benefit of priority from Japanese Patent Application No. 2025-018537 filed on Feb. 6, 2025. The entire disclosures of the above application are incorporated herein by reference.

### TECHNICAL FIELD

The present disclosure relates to a switching element and a method for manufacturing the same.

### BACKGROUND

It has been known a trench gate type switching element having a plurality of p-type electric field relaxation regions below trenches. Each of the electric field relaxation regions extends linearly within a plane of a substrate, that is, within a substrate plane parallel to an upper surface of the substrate. N-type regions are provided between the electric field relaxation regions, as n-type spacing regions. The switching element has a super junction structure below the electric field relaxation regions. The super junction structure has a plurality of super junction p-type regions and a plurality of super junction n-type regions. Each of the super junction p-type regions and each of the super junction n-type regions extend linearly in the direction intersecting the electric field relaxation regions in the substrate plane. The super junction p-type regions and the super junction n-type regions are alternately arranged. The super junction p-type regions and the super junction n-type regions are in contact with the electric field relaxation regions and the n-type spacing regions from below.

### SUMMARY

According to an aspect of the present disclosure, a switching element includes: a semiconductor substrate formed with a plurality of trenches on an upper surface thereof; and a gate insulating film and a gate electrode disposed in each of the plurality of trenches. The semiconductor substrate may include: a source region of an n-type disposed in a space between the plurality of trenches and in contact with the gate insulating film; a body region of a p-type disposed in the space between the plurality of trenches and in contact with the gate insulating film below the source region; a plurality of electric field relaxation regions of the p-type linearly extending in a first direction along a substrate plane, which is parallel to the upper surface of the semiconductor substrate, and disposed at intervals in a second direction intersecting with the first direction in the substrate plane, each of the plurality of electric field relaxation regions at least having a portion disposed lower than the plurality of trenches; a plurality of n-type spacing regions each disposed in a space between the plurality of electric field relaxation regions; a plurality of super junction p-type regions linearly extending in the second direction, disposed at intervals in the first direction and being in contact with the plurality of electric field relaxation regions and the plurality of n-type spacing regions from below; and a plurality of super junction n-type regions disposed in spaces between the plurality of super junction p-type regions and being in contact with the electric field relaxation regions and the plurality of n-type spacing regions from below. Each of the plurality of super junction n-type regions may include: a low charge quantity region that is in contact with the plurality of electric field relaxation regions and the plurality of n-type spacing regions from below; and a high charge quantity region that is in contact with the low charge quantity region from below and has an n-type charge quantity higher than that in the low charge quantity region.

### BRIEF DESCRIPTION OF DRAWINGS

Objects, features, and advantages of the present disclosure will become more apparent from the following detailed description made with reference to the accompanying drawings, in which like parts are designated by like reference numbers and in which:

FIG. 1 is a cross-sectional perspective view of a switching element according to a first embodiment;

FIG. 2 is a diagram showing a positional relationship between electric field relaxation regions and super junction p-type regions as viewed along a z direction;

FIG. 3 is a cross-sectional view along an xz-plane at a position including a super junction n-type region;

FIG. 4 is a diagram including a partial cross-sectional view along a yz-plane at a position including n-type spacing regions and a graph showing the distribution of n-type charge quantity along a line A;

FIG. 5 is a diagram including a partial cross-sectional view along the yz-plane at a position including an electric field relaxation region of a switching element of a comparative example and a graph showing the distribution of electric field along a ling B;

FIG. 6 is a diagram including a partial cross-sectional view along the yz-plane at a position including an electric field relaxation region of the switching element according to the first embodiment and a graph showing the distribution of electric field along a line C;

FIG. 7 is a diagram for explaining a method for manufacturing the switching element according to the first embodiment; and

FIG. 8 is a diagram for explaining the method for manufacturing the switching element according to the first embodiment;

FIG. 9 is a cross-sectional perspective view of a switching element according to a second embodiment;

FIG. 10 is a diagram including a partial cross-sectional view along the yz-plane at a position including an n-type spacing region of the switching element according to the second embodiment and a graph showing the distribution of n-type charge quantity along a line D;

FIG. 11 is a diagram for explaining a method for manufacturing the switching element according to the second embodiment;

FIG. 12 is a diagram for explaining the method for manufacturing the switching element according to the second embodiment;

FIG. 13 is a cross-sectional perspective view of the switching element according to the second embodiment;

FIG. 14 is a diagram including a partial cross-sectional view along the yz-plane at a position including an electric field relaxation region of the switching element according to the second embodiment and a graph showing the distribution of n-type charge quantity along a line E and the distribution of p-type charge quantity along a line F;

FIG. 15 is a partial cross-sectional view of a switching element according to a modification; and

FIG. 16 is a cross-sectional perspective view of a switching element according to another modification.

### DETAILED DESCRIPTION

There is a trench gate type switching element having a plurality of p-type electric field relaxation regions disposed below trenches. Each of the electric field relaxation regions extends linearly within a plane of a substrate, that is, within a substrate plane parallel to an upper surface of the substrate. N-type regions are provided between the electric field relaxation regions. Hereinafter, the n-type region disposed between the electric field relaxation regions will be also referred to as an “n-type spacing region.” In the switching element having the electric field relaxation region, a depletion layer extends from the electric field relaxation region to its periphery when the switching element is turned off, thereby suppressing electric field concentration at the bottom end of the trench. As an example, the electric field relaxation regions may extend along the trenches. As another example, the electric field relaxation regions may extend in a direction intersecting the trenches. As long as at least a portion of the electric field relaxation regions is positioned below the trenches, the effect of electric field relaxation can be achieved.

In addition, the switching element has a super junction structure below the electric field relaxation regions. The super junction structure has a plurality of super junction p-type regions and a plurality of super junction n-type regions. Each of the super junction p-type regions and each of the super junction n-type regions extend linearly in the direction intersecting with the electric field relaxation regions in the substrate plane. The super junction p-type regions and the super junction n-type regions are alternately arranged. The super junction p-type regions and the super junction n-type regions are in contact with the electric field relaxation regions and the n-type spacing regions from below. Thus, the super junction structure can improve the breakdown voltage of the switching element.

In the switching element described above, the super junction n-type regions are in contact with the n-type spacing regions from below. It was found that as n-type impurities are diffused from the n-type spacing region to the upper end of the super junction n-type region, an n-type region is formed at the upper end of the super junction n-type region with a higher n-type impurity concentration than that of a part below the upper end. When the n-type region with the higher n-type impurity concentration exists at the upper end of the super junction n-type region, an electric field concentrates at the interface between the n-type region with the higher n-type impurity concentration and the field relaxation region, resulting in a decrease in the breakdown voltage of the switching element.

The present disclosure provides a technique for improving the breakdown voltage of a switching element having an electric field relaxation region and a super junction structure.

According to an aspect of the present disclosure, a switching element includes a semiconductor substrate formed with a plurality of trenches on its upper surface, and a gate insulating film and a gate electrode disposed in each of the plurality of trenches. The semiconductor substrate includes: a source region of an n-type disposed in a space between the plurality of trenches and in contact with the gate insulating film; a body region of a p-type disposed in the space between the plurality of trenches and in contact with the gate insulating film below the source region; a plurality of electric field relaxation regions of the p-type linearly extending in a first direction along a substrate plane, which is parallel to the upper surface of the semiconductor substrate, and disposed at intervals in a second direction intersecting with the first direction in the substrate plane, each of the plurality of electric field relaxation regions at least having a portion disposed lower than the plurality of trenches; a plurality of n-type spacing regions each disposed in a space between the plurality of electric field relaxation regions; a plurality of super junction p-type regions linearly extending in the second direction, disposed at intervals in the first direction and being in contact with the plurality of electric field relaxation regions and the plurality of n-type spacing regions from below; and a plurality of super junction n-type regions disposed in spaces between the plurality of super junction p-type regions and being in contact with the p-type electric field relaxation regions and the plurality of n-type spacing regions from below. Each of the plurality of super junction n-type regions includes: a low charge quantity region that is in contact with the plurality of electric field relaxation regions and the plurality of n-type spacing regions from below; and a high charge quantity region that is in contact with the low charge quantity region from below and has an n-type charge quantity higher than that in the low charge quantity region.

In this switching element, each of the super junction n-type region has the low charge quantity region that is in contact with the field relaxation regions and the n-type spacing regions from below. Accordingly, it is possible to suppress electric field concentration at the interface between the super junction n-type region and the field relaxation region, thereby improving the breakdown voltage of the switching element.

Embodiments of the present disclosure will be described hereinafter with reference to the drawings.

### First Embodiment

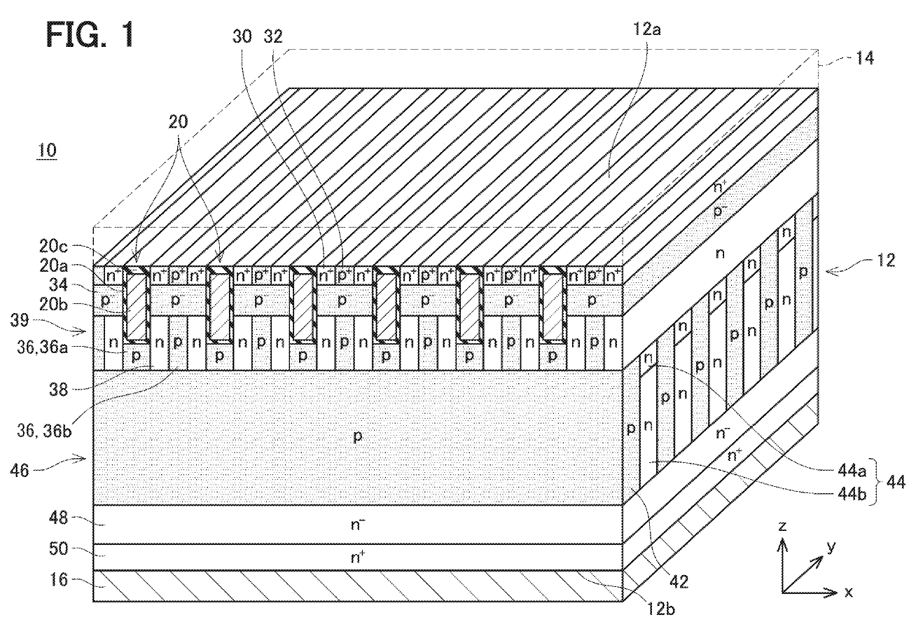

As shown in FIG. 1, a switching element 10 of a first embodiment is a metal oxide semiconductor field effect transistor (MOSFET). The switching element 10 includes a semiconductor substrate 12, a source electrode 14, and a drain electrode 16. The semiconductor substrate 12 is made of silicon carbide (SiC). However, the semiconductor substrate 12 may be made of other semiconductor materials such as silicon (Si) or gallium nitride (GaN). The source electrode 14 covers an upper surface 12a of the semiconductor substrate 12. The drain electrode 16 covers a lower surface 12b of the semiconductor substrate 12. Hereinafter, a direction within a plane parallel to the upper surface 12a of the semiconductor substrate 12 (i.e., within the substrate plane) is referred to as an x direction, and a direction perpendicular to the x direction within the substrate plane is referred to as a y direction. Further, a thickness direction of the semiconductor substrate 12 is referred to as a z direction.

The semiconductor substrate 12 is formed with a plurality of trenches 20 on the upper surface 12a. Each of the trenches 20 extends linearly along the y direction in the upper surface 12a. The trenches 20 are arranged at intervals in the x direction.

A gate insulating film 20a and a gate electrode 20b are provided in each of the trenches 20. The gate insulating film 20a covers an inner surface of the trench 20. The gate electrode 20b is disposed at a position surrounded by the gate insulating film 20a. The gate electrode 20b is insulated from the semiconductor substrate 12 by the gate insulating film 20a. An upper surface of the gate electrode 20b is covered with an interlayer insulating film 20c. The gate electrode 20b is insulated from the source electrode 14 by the interlayer insulating film 20c. Hereinafter, a semiconductor region located in a space between the trenches 20 is referred to as an inter-trench semiconductor region.

The semiconductor substrate 12 has a plurality of source regions 30 of an n-type, a plurality of contact regions 32 of a p-type, and a body region 34 of a p-type. The source region 30, the contact region 32, and the body region 34 are disposed within each inter-trench semiconductor region.

Each source region 30 is an n-type region having a high n-type impurity concentration. Each source region 30 is disposed at a position including the upper surface 12a of the semiconductor substrate 12, and is in ohmic contact with the source electrode 14. Each source region 30 is in contact with the gate insulating film 20a at the upper end of a side wall of the trench 20. Each source region 30 extends linearly in the y direction.

Each contact region 32 is a p-type region having a high p-type impurity concentration. Each contact region 32 is disposed adjacent to the source region 30. Each contact region 32 is disposed in a range including the upper surface 12a of the semiconductor substrate 12, and is in ohmic contact with the source electrode 14. Each contact region 32 extends linearly in the y direction.

The body region 34 is a p-type region having a p-type impurity concentration lower than that of the contact region 32. The body region 34 is in contact with the source region 30 and the contact region 32 from below. The body region 34 is electrically connected to the source electrode 14 via the contact region 32. The body region 34 is in contact with the gate insulating film 20a below the source region 30.

An electric field relaxation structure 39 is provided below the body region 34. The electric field relaxation structure 39 has a configuration in which a plurality of electric field relaxation regions 36 of a p-type and a plurality of n-type spacing regions 38 of an n-type are alternately arranged in the x direction. In other words, the plurality of electric field relaxation regions 36 are arranged at intervals in the x direction, and the n-type spacing regions 38 are disposed in the spaces between the electric field relaxation regions 36.

The plurality of electric field relaxation regions 36 include a plurality of first electric field relaxation regions 36a disposed directly under the trenches 20, and a plurality of second electric field relaxation regions 36b disposed directly under the body region 34.

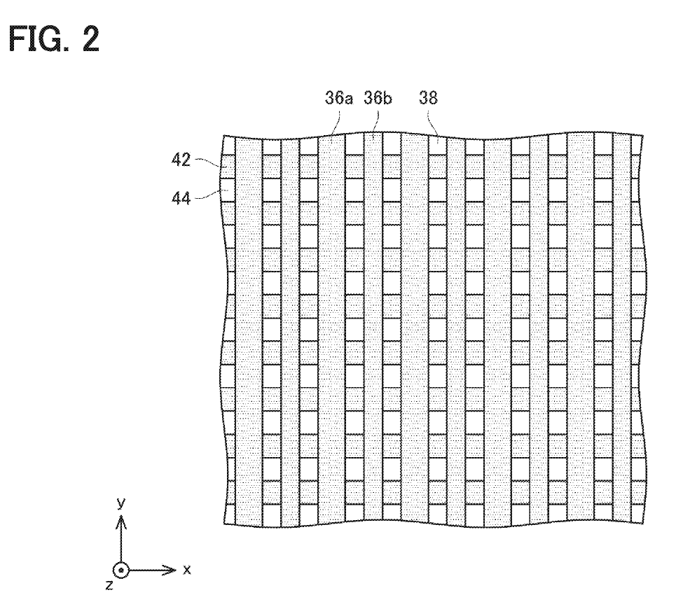

Each first electric field relaxation region 36a is in contact with the gate insulating film 20a at a bottom surface of the trench 20. The entirety of each first electric field relaxation region 36a is disposed below a lower end of the trench 20. As shown in FIG. 2, each first electric field relaxation region 36a extends linearly in the y direction along the trench 20.

As shown in FIG. 1, each second electric field relaxation region 36b is disposed at a position spaced apart from the trench 20 in the x direction. Each second electric field relaxation region 36b is in contact with the body region 34 from below. Each second electric field relaxation region 36b extends from a position in contact with the body region 34 to a position lower than the lower end of the trench 20. Accordingly, a portion of each second electric field relaxation region 36b is disposed below the lower end of the trench 20. As shown in FIG. 2, each second electric field relaxation region 36b extends linearly in the y direction. The first electric field relaxation regions 36a and the second electric field relaxation regions 36b are alternately arranged in the x direction.

Each n-type spacing region 38 is in contact with the body region 34 from below. Each n-type spacing region 38 extends from a position in contact with the body region 34 to a position below the lower end of the trench 20. In a range above the lower end of the trench 20, each n-type spacing region 38 is located within the space between the trench 20 and the second electric field relaxation region 36b. In a range below the lower end of the trench 20, each n-type spacing region 38 is located within the space between the first electric field relaxation region 36a and the second electric field relaxation region 36b. Each n-type spacing region 38 is in contact with the gate insulating film 20a below the body region 34.

A super junction structure 46 is provided below the electric field relaxation structure 39. Hereinafter, the super junction will be simply referred to as “SJ.” The SJ structure 46 has a configuration in which a plurality of SJ p-type regions 42 and a plurality of SJ n-type regions 44 are alternately arranged in the y direction.

As shown in FIG. 2, each SJ p-type region 42 extends linearly in the x direction. The plurality of SJ p-type regions 42 are arranged at intervals in the y direction. As shown in FIG. 1, each SJ p-type region 42 is in contact with the first electric field relaxation regions 36a, the second electric field relaxation regions 36b, and the n-type spacing regions 38 from below.

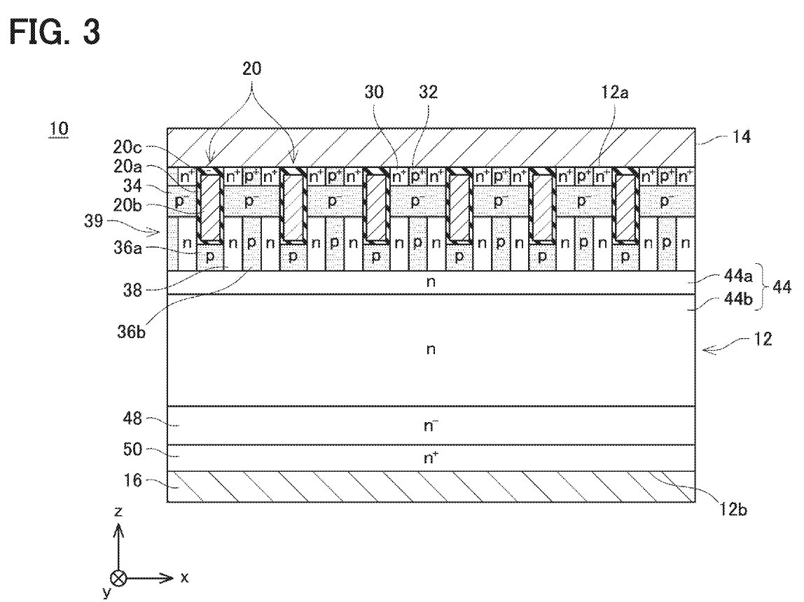

As shown in FIG. 2, each SJ n-type region 44 extends linearly in the x direction. Each SJ n-type region 44 is disposed within a space between the SJ p-type regions 42. As shown in FIG. 3, each SJ n-type region 44 is in contact with the first electric field relaxation regions 36a, the second electric field relaxation regions 36b, and the n-type spacing regions 38 from below.

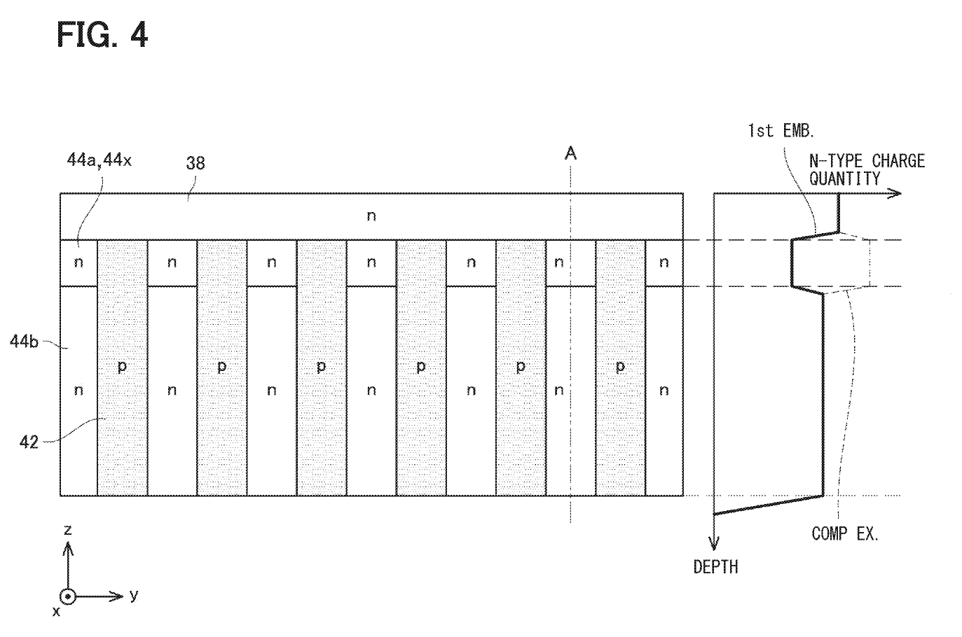

Each SJ n-type region 44 has a low charge quantity region 44a and a high charge quantity region 44b. The low charge quantity region 44a is disposed at an upper end of the SJ n-type region 44. The high charge quantity region 44b is disposed below the low charge quantity region 44a. The low charge quantity region 44a has an n-type charge quantity lower than that in the high charge quantity region 44b. In this specification, the n-type charge quantity refers to the value obtained by integrating an effective donor concentration within the SJ n-type region 44 in the width direction (e.g., in the y direction in the present embodiment) of the SJ n-type region 44. In addition, the effective donor concentration refers to the value obtained by subtracting an acceptor concentration from a donor concentration in a semiconductor region. In the present embodiment, the low charge quantity region 44a has an n-type impurity concentration lower than that in the high charge quantity region 44b. More specifically, the n-type impurity concentration of the low charge quantity region 44a is at least 0.4 times and at most 0.9 times then-type impurity concentration of the high charge quantity region 44b. In addition, the width of the low charge quantity region 44a is approximately equal to the width of the high charge quantity region 44b, and the p-type impurity concentration of the low charge quantity region 44a is approximately equal to the p-type impurity concentration of the high charge quantity region 44b. Accordingly, as shown in FIG. 4, the n-type charge quantity in the low charge quantity region 44a is lower than the n-type charge quantity in the high charge quantity region 44b. In the present embodiment, the n-type impurity concentration of the high charge quantity region 44b is lower than the n-type impurity concentration of the n-type spacing region 38. Accordingly, the n-type charge quantity in the high charge quantity region 44b is lower than the n-type charge quantity in the n-type spacing region 38. As shown in FIG. 3, the low charge quantity region 44a is in contact with the first electric field relaxation regions 36a, the second electric field relaxation regions 36b, and the n-type spacing regions 38 from below. The high charge quantity region 44b is in contact with the low charge quantity region 44a from below.

A drift region 48 and a drain region 50 are provided below the SJ structure 46. The drift region 48 is ann-type region having an n-type impurity concentration lower than that in the low charge quantity region 44a. The drift region 48 is in contact with the SJ p-type regions 42 and the SJ n-type regions 44 from below. The drain region 50 has ann-typeimpurity concentration higher than that in then-type spacing region 38. The drain region 50 is in contact with the drift region 48 from below. The drain region 50 is in ohmic contact with the drain electrode 16 at the lower surface 12b.

Next, the operation of the switching element 10 will be described. When the switching element 10 is operated, the drain electrode 16 is applied with a higher potential than the source electrode 14. When a gate-on potential (that is, a potential higher than a gate threshold) is applied to the gate electrode 20b, a channel is formed in the body region 34 near the gate insulating film 20a. The channel connects the source region 30 and the n-type spacing region 38 located below. As a result, electrons flow from the source region 30 to the drain region 50 via the channel, the n-type spacing region 38, the SJ n-type region 44, and the drift region 48. When the potential of the gate electrode 20b is lowered to a value below the gate threshold, the channel disappears and the flow of electrons stops. That is, the switching element 10 is turned off. When the switching element 10 is turned off, a depletion layer spreads from the body region 34 and the electric field relaxation region 36 into the n-type spacing region 38. As a result, the entire n-type spacing region 38 is depleted. Additionally, in the SJ structure 46, depletion layers spread from the interface between the SJ p-type region 42 and the SJ n-type region 44 into both the SJ p-type region 42 and the SJ n-type region 44. As a result, the SJ p-type region 42 and the SJ n-type region 44 are entirely depleted. The depletion layers formed in this manner maintain the voltage between the drain electrode 16 and the source electrode 14. In the vicinity of the lower end of the trench 20, the electric field applied to the gate insulating film 20a is alleviated by the depletion layer extending from the electric field relaxation region 36 into the n-type spacing region 38. As a result, the breakdown voltage of the switching element 10 is improved.

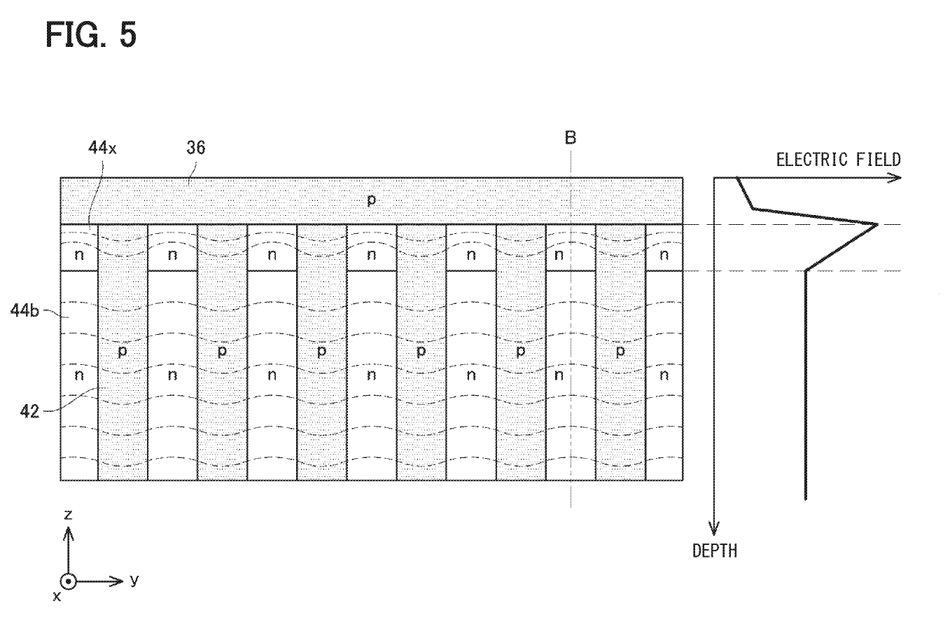

In FIG. 4, a graph with a dashed line shows the distribution of the n-type charge quantity in a switching element of a comparative example. In the switching element of the comparative example, a region 44x with a high n-type charge quantity is locally disposed at the upper end of each SJ n-typeregion 44. The region 44x at which the n-type charge quantity is locally high is formed because donors in the n-type spacing region 38 are diffused into the upper end of the SJ n-type region 44 during a manufacturing process of the switching element. When the region 44x with the high n-type charge quantity is provided at the upper end of the SJ n-type region 44 in this manner, the region 44x comes into contact with the electric field relaxation region 36 from below, as shown in FIG. 5. When the switching element of the comparative example is turned off and the SJ structure 46 is depleted, the density of equipotential lines increased in the region 44x in which the n-type charge quantity is high, as shown in FIG. 5. Thus, a high electric field is generated at the interface between the electric field relaxation region 36 and the SJ n-type region 44 (i.e., the region 44x). As a result, a high electric field is generated within the electric field relaxation region 36, causing a leakage current.

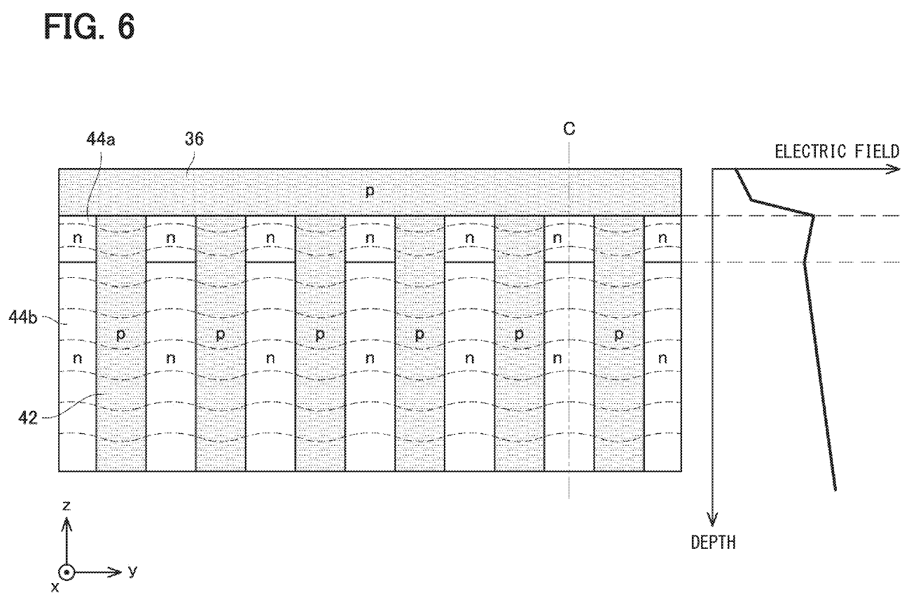

In contrast, as described above, in the switching element 10 of the first embodiment, the low charge quantity region 44a in which the n-type charge quantity is low is provided at the upper end of the SJ n-type region 44. Therefore, when the switching element 10 of the first embodiment is turned off and the SJ structure 46 is depleted, the density of equipotential lines in the low charge quantity region 44a is low, as shown in FIG. 6, and the electric field at the interface between the electric field relaxation region 36 and the SJ n-type region 44 (i.e., the low charge quantity region 44a) is alleviated. As a result, since the electric field within the electric field relaxation region 36 is alleviated, the occurrence of leakage current can be suppressed. Therefore, the switching element 10 of the first embodiment has a higher breakdown voltage.

In addition, in the first embodiment, the low charge quantity region 44a is locally provided at the upper end of the SJ n-type region 44. Therefore, even if the low charge quantity region 44a is provided, the balance of the charge quantity between the SJ n-type region 44 and the SJ p-type region 42 can be maintained, and the SJ structure 46 can be suitably depleted. Even if the low charge quantity region 44a is provided, a high breakdown voltage can be ensured in the SJ structure 46.

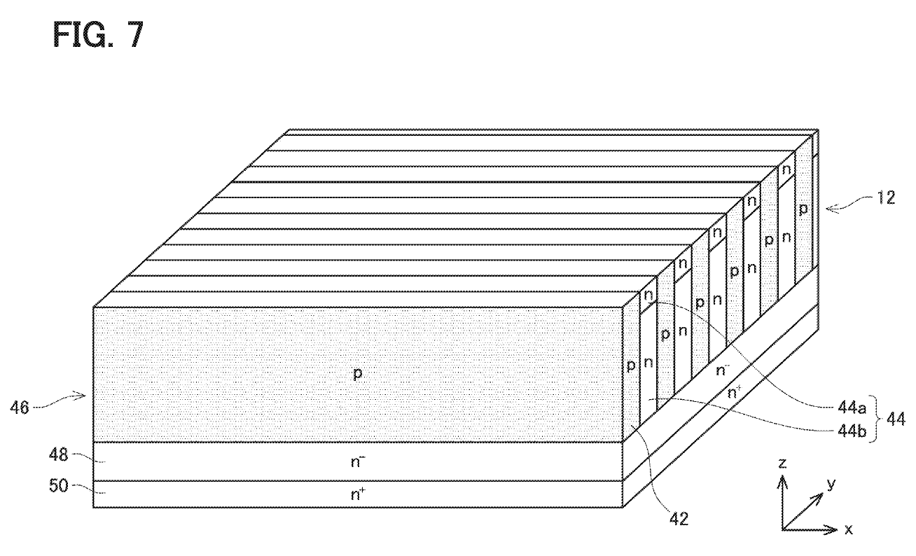

Next, a method for manufacturing the switching element 10 of the first embodiment will be described. The switching element 10 is manufactured from a semiconductor substrate having the drain region 50. First, as shown in FIG. 7, the drift region 48, the SJ p-type regions 42, and the SJ n-type regions 44 are formed on the drain region 50 by epitaxial growth and ion implantation. In this case, the SJ n-type region 44 is formed so that the low charge quantity region 44a is provided at the upper end of the SJ n-type region 44, and the high charge quantity region 44b is provided under the low charge quantity region 44a.

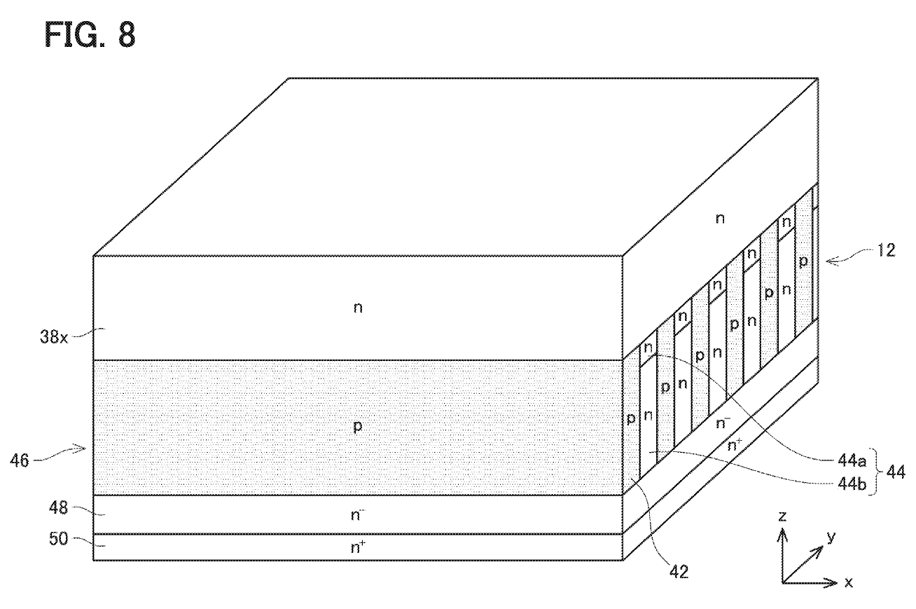

Next, as shown in FIG. 8, an n-type layer 38x, which corresponds to the n-type spacing region 38, is formed above the SJ structure 46 by epitaxial growth. At this time, donors diffuse from the n-type layer 38x into the upper end of each of the SJ n-type region 44 (i.e., the low charge quantity region 44a). However, since the n-type charge quantity in the low charge quantity region 44a is originally low, even if the donors diffuse into the low charge quantity region 44a, the n-type charge quantity in the low charge quantity region 44a is maintained at a low value.

Thereafter, by performing ion implantation into the n-type layer 38x, the electric field relaxation regions 36, the body region 34, the contact regions 32, and the source regions 30 are formed. In addition, by etching, sputtering, and the like, the trenches 20, the gate insulating films 20a, the gate electrodes 20b, the interlayer insulating films 20c, the source electrode 14, and the drain electrode 16 are formed. In this way, the switching element 10 shown in FIG. 1 is completed.

It should be noted that the manufacturing method described above is merely an example, and the switching element 10 may be manufactured by other methods. For example, in the manufacturing method described above, the n-type layer 38x is formed by the epitaxial growth. Alternatively, the n-type layer 38x may be formed by ion implantation or the like. Also in this case, even if the donors diffuse from the n-type layer 38x into the low charge quantity region 44a, the n-type charge quantity in the low charge quantity region 44a is maintained at a low value. In addition, the order of the processed may be changed from that in the manufacturing method described above.

### Second Embodiment

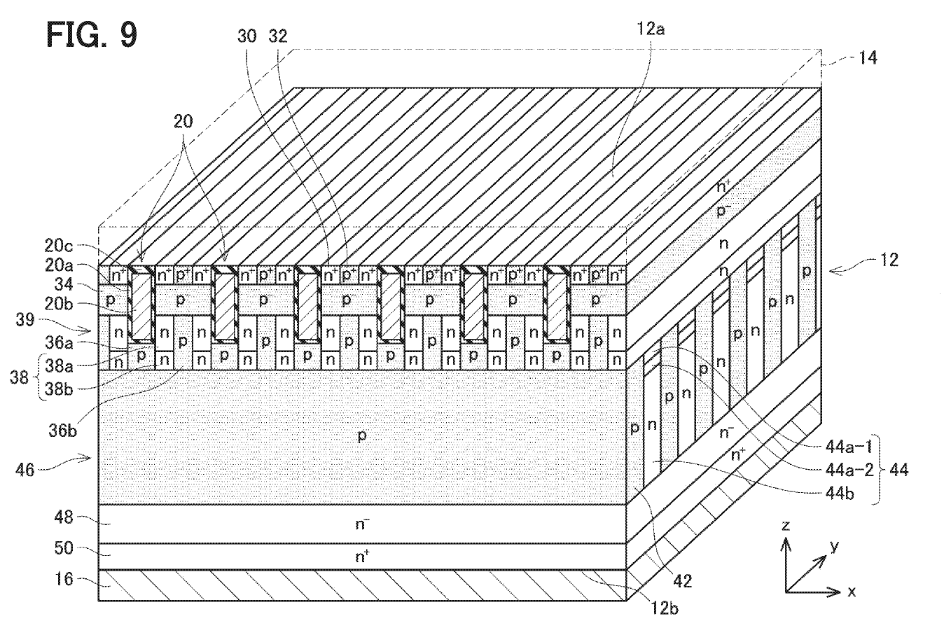

As shown in FIG. 9, in a switching element of a second embodiment, each of the n-type spacing regions 38 has a first n-type spacing region 38a and a second n-type spacing region 38b. The second n-type spacing region 38b has an n-type impurity

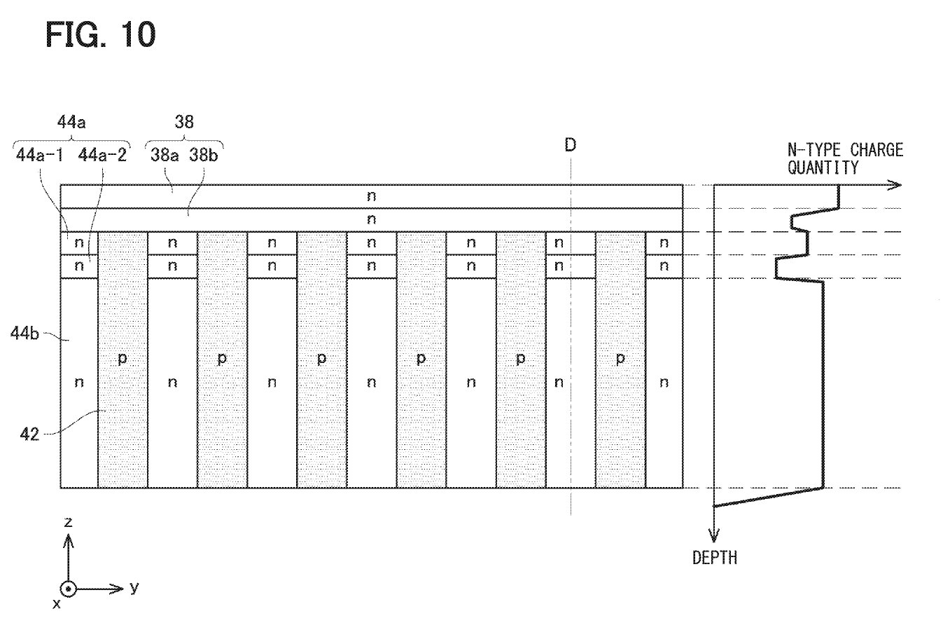

concentration lower than that in the first n-type spacing region 38a. Therefore, as shown in FIG. 10, the second n-type spacing region 38b has the n-type charge quantity lower than that in the first n-type spacing region 38a. The first n-type spacing region 38a is disposed below the body region 34, and the second n-type spacing region 38b is disposed below the first n-type spacing region 38a. Additionally, in the switching device of the second embodiment, each of the low charge quantity region 44a has a first low charge quantity region 44a-1 and a second low charge quantity region 44a-2. The second low charge quantity region 44a-2 has an n-type impurity concentration lower than that in the first low charge quantity region 44a-1. Therefore, as shown in FIG. 10, the second low charge quantity region 44a-2 has an n-type charge quantity lower than that in the first low charge quantity region 44a-1. The first low charge quantity region 44a-1 is in contact with the second n-type spacing regions 38b and the electric field relaxation regions 36 from below. The second low charge quantity region 44a-2 is in contact with the first low charge quantity region 44a-1 from below. The high charge quantity region 44b is in contact with the second low charge quantity region 44a-2 from below. As shown in FIG. 10, the n-type charge quantity decreases in the order of the first n-type spacing region 38a, the high charge quantity region 44b, the first low charge quantity region 44a-1, the second n-type spacing region 38b, and the second low charge quantity region 44a-2. In the present embodiment, the n-type impurity concentration of the first low charge quantity region 44a-1 is at least 0.4 times and at most 0.9 times the n-type impurity concentration of the high charge quantity region 44b. Therefore, the n-type charge quantity in the first low charge quantity region 44a-1 is at least 0.4 times and at most 0.9 times the n-type charge quantity in the high charge quantity region 44b. The other structures of the switching element of the second embodiment are similar to those in the first embodiment.

In the switching element of the second embodiment, the first low charge quantity region 44a-1, which has the n-type charge quantity lower than that in the high charge quantity region 44b, is in contact with the electric field relaxation regions 36 from below. In the second embodiment, therefore, the electric field in the electric field relaxation regions 36 can be reduced, similarly to the first embodiment. Accordingly, the switching element of the second embodiment also has a high breakdown voltage.

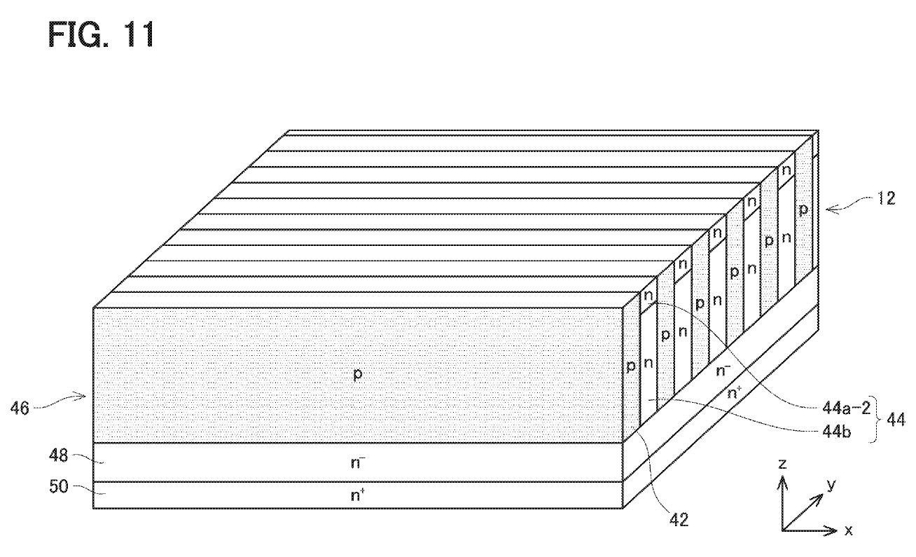

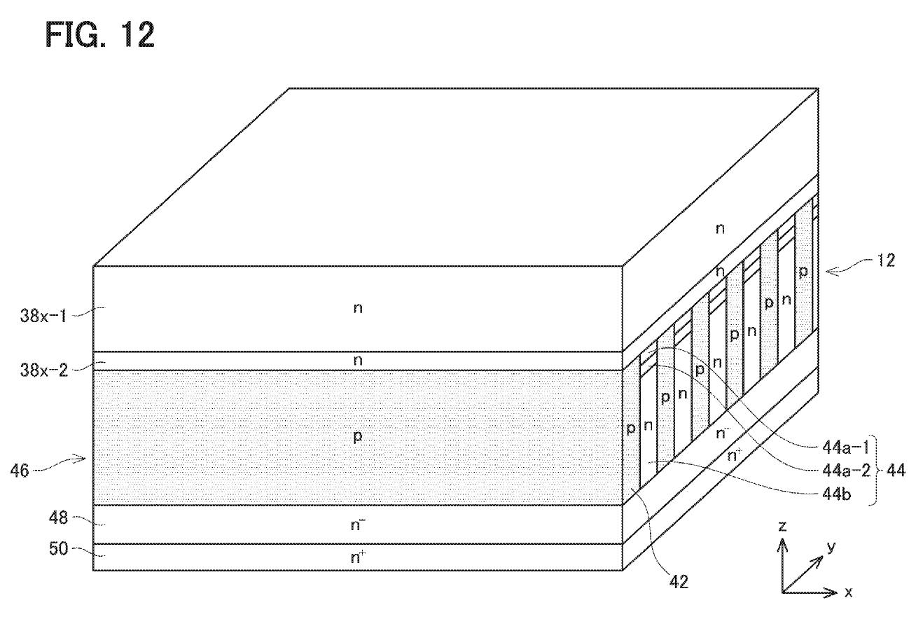

In a manufacturing method of the switching element of the second embodiment, as shown in FIG. 11, the SJ n-type region 44 is formed so that the second low charge quantity region 44a-2 is positioned above the high charge quantity region 44b. Next, as shown in FIG. 12, ann-type layer 38x-1 and an n-type layer 38x-2 are formed above the SJ structure 46 by epitaxial growth. The n-type layer 38x-1 is an n-type layer having the n-type charge quantity corresponding to the first n-type spacing region 38a, and the n-type layer 38x-2 is an n-type layer having the n-type charge quantity corresponding to the second n-type spacing region 38b. More specifically, first, the n-type layer 38x-2 is formed above the SJ structure 46 by epitaxial growth. Next, the n-type layer 38x-1 is formed above the n-type layer 38x-2 by epitaxial growth.

When the n-type layer 38x-2 is formed above the SJ structure 46, donors diffuse from the n-type layer 38x-2 into the second low charge quantity region 44a-2. As a result, the n-type charge quantity increases at the upper end of the second low charge quantity region 44a-2, and the first low charge quantity region 44a-1 is thus formed. However, since the n-type charge quantity in the n-type layer 38x-2 is low, the n-type charge quantity in the first low charge quantity region 44a-1 is not increased so high, and is lower than the n-type charge quantity in the high charge quantity region 44b. Thereafter, respective parts are formed in a similar manner to the first embodiment. In this way, the switching element as shown in FIG. 9 is manufactured.

As described above, in the manufacturing method of the second embodiment, the n-type charge quantity in the n-type layer 38x-2 is low. Therefore, it is possible to reduce the increase in the n-type charge quantity in the first low charge quantity region 44a-1. Accordingly, the switching element of the second embodiment having a high breakdown voltage can be manufactured.

### Third Embodiment

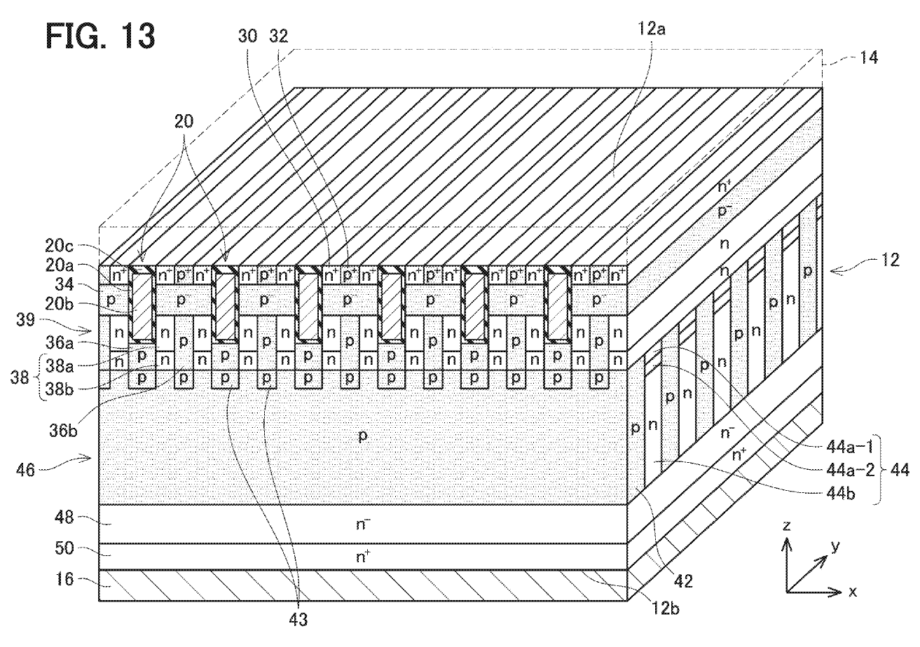

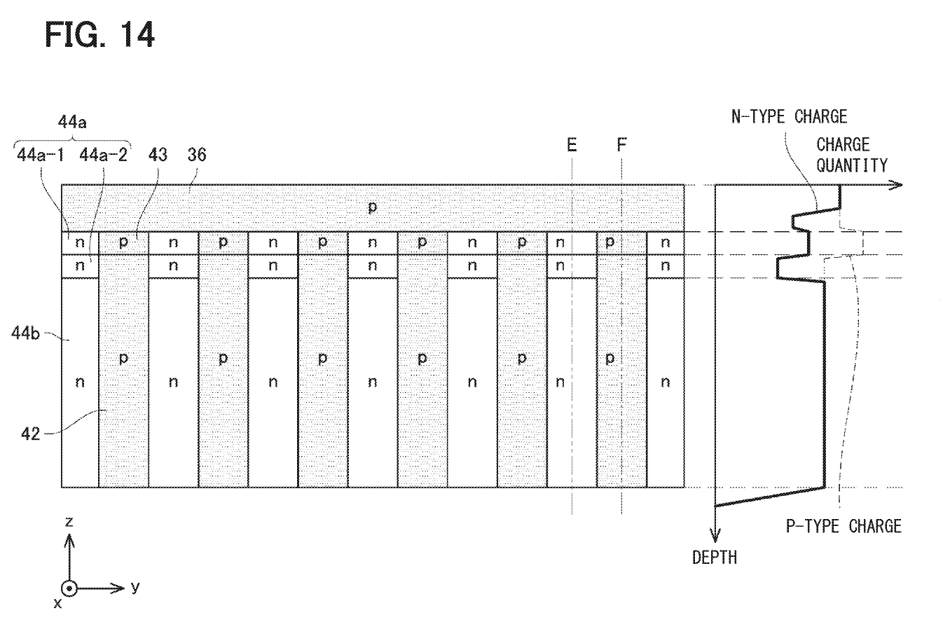

As shown in FIG. 13, in a switching element of a third embodiment, a p-type connection region 43 is provided at each connection portion between each electric field relaxation region 36 and each SJ p-type region 42. The p-type connection region 43 has a p-type impurity concentration that is higher than the p-type impurity concentration in the electric field relaxation region 36 located above the p-type connection region 43 and the p-type impurity concentration in the SJ p-type region 42 located below the p-type connection region 43. Therefore, as shown in FIG. 14, the p-type charge quantity in the p-type connection region 43 is higher than a p-type charge quantity in the electric field relaxation region 36 located above the p-type connection region 43, and higher than a p-type charge quantity in the SJ p-type region 42 located below the p-type connection region 43. It should be noted that the p-type charge quantity is a value obtained by integrating the effective acceptor density (the value obtained by subtracting the donor density from the acceptor density) in the width direction of the p-type region. The p-type charge quantity in the p-type connection region 43 is higher than the n-type charge quantity in the first low charge quantity region 44a-1. The other structures of the switching element of the third embodiment are similar to those in the first embodiment.

In the switching element of the third embodiment, the p-type connection region 43 having the high p-type charge quantity is disposed adjacent to the first low charge quantity region 44a-1. Therefore, when the switching element is turned off, the depletion layer easily spreads from the p-type connection region 43 to the first low charge quantity region 44a-1, and the first low charge quantity region 44a-1 is thus easily depleted. As a result, the electric field in the electric field relaxation region 36 can be reduced more effectively. Accordingly, the switching element of the third embodiment also has a high breakdown voltage.

In the manufacturing process of the switching element of the third embodiment, processing up to the state shown in FIG. 12 is performed in a similar manner to those in the second embodiment. Thereafter, when the electric field relaxation regions 36 are formed by implanting the p-type impurities into the n-type layers 38x-1 and 38x-2, the p-type impurities diffuse from the electric field relaxation region 36 into the upper end of each SJ p-type region 42 (i.e., each connection portion between each electric field relaxation region 36 and each SJ p-type region 42). As a result, the p-type impurity concentration increases in each connection portion, and the p-type connection regions 43 with a high p-type impurity concentration are formed. Accordingly, the switching element of the third embodiment having a high breakdown voltage can be manufactured.

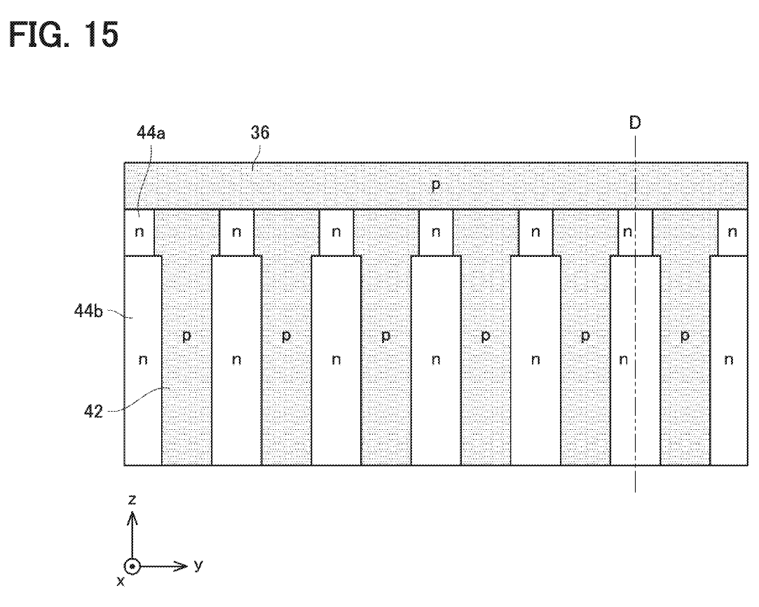

In the embodiments described above, the n-type impurity concentration in the low charge quantity region 44a is lower than the n-type impurity concentration in the high charge quantity region 44b, so that the n-type charge quantity in the low charge quantity region 44a is lower than that in the high charge quantity region 44b. In a modification, as shown in FIG. 15, the width of the low charge quantity region 44a may be narrower than the width of the high charge quantity region 44b, so that then-type charge quantity in the low charge quantity region 44a is lower than the n-type charge quantity in the high charge quantity region 44b. In this case, the n-type impurity concentration of the low charge quantity region 44a may be equal to the n-type impurity concentration of the high charge quantity region 44b. Also in such a configuration, it is possible to suppress the electric field concentration in the electric field relaxation region 36.

In the embodiments described above, the electric field relaxation region 36 includes the first electric field relaxation region 36a disposed directly under the trench 20 and the second electric field relaxation region 36b disposed directly under the body region 34. However, the electric field relaxation region 36 may include either the first electric field relaxation region 36a or the second electric field relaxation region 36b.

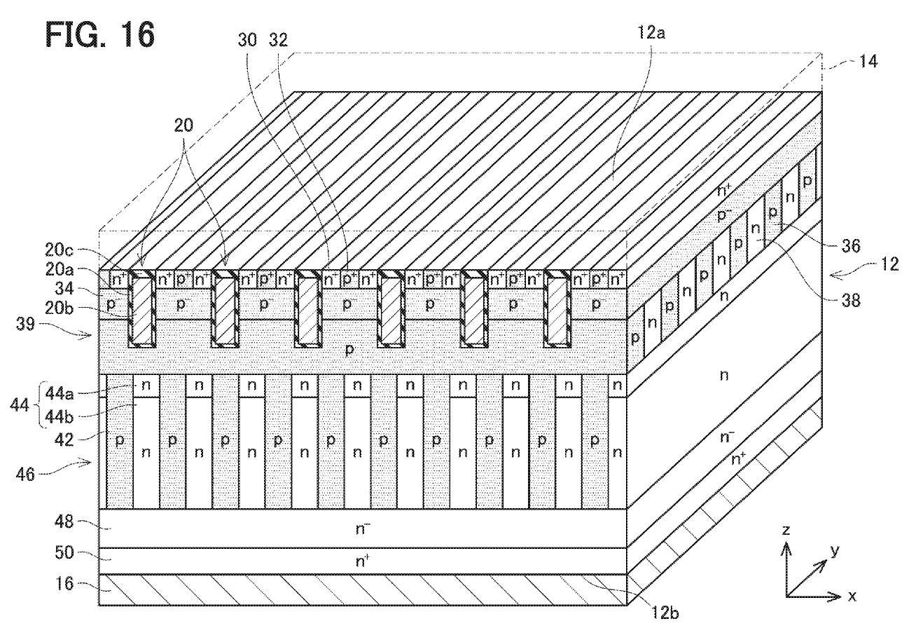

In the embodiments described above, the electric field relaxation region 36 extends in a direction parallel to the trench 20 (i.e., the y direction), and the SJ p-type region 42 extends in a direction intersecting with the trench 20 (i.e., the x direction). In a modification, as shown in FIG. 16, the electric field relaxation region 36 may extend in a direction intersecting with the trench 20, and the SJ p-type region 42 may extend in a direction parallel to the trench 20.

In the embodiments described above, the electric field relaxation region 36 is in contact with the lower end of the trench 20. As another example, the electric field relaxation region 36 may be disposed at a position lower than the lower end of the trench 20.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A switching element comprising:
a semiconductor substrate formed with a plurality of trenches on an upper surface thereof; and
a gate insulating film and a gate electrode disposed in each of the plurality of trenches, wherein
the semiconductor substrate includes:
a source region of an n-type disposed in a space between the plurality of trenches and in contact with the gate insulating film;
a body region of a p-type disposed in the space between the plurality of trenches and in contact with the gate insulating film below the source region;
a plurality of electric field relaxation regions of the p-type linearly extending in a first direction along a substrate plane, which is parallel to the upper surface of the semiconductor substrate, and disposed at intervals in a second direction intersecting with the first direction in the substrate plane, each of the plurality of electric field relaxation regions at least having a portion disposed lower than the plurality of trenches;
a plurality of n-type spacing regions each disposed in a space between the plurality of electric field relaxation regions;
a plurality of super junction p-type regions linearly extending in the second direction, disposed at intervals in the first direction, and being in contact with the plurality of electric field relaxation regions and the plurality of n-type spacing regions from below; and
a plurality of super junction n-type regions disposed in spaces between the plurality of super junction p-type regions and being in contact with the electric field relaxation regions and the plurality of n-type spacing regions from below, and
each of the plurality of super junction n-type regions includes:
a low charge quantity region that is in contact with the plurality of electric field relaxation regions and the plurality of n-type spacing regions from below; and
a high charge quantity region that is in contact with the low charge quantity region from below and has an n-type charge quantity higher than that in the low charge quantity region.

2. The switching element according to claim 1, wherein
each of the plurality of n-type spacing regions includes:
a first n-type spacing region; and
a second n-type spacing region that is in contact with the first n-type spacing region from below and has an n-type charge quantity lower than that in the first n-type spacing region, and
each of the plurality of low charge quantity regions includes:
a first low charge quantity region that is in contact with the second n-type spacing region from below, and
a second low charge quantity region that is in contact with the first low charge quantity region from below and has an n-type charge quantity lower than that in the first low charge quantity region.

3. The switching element according to claim 2, wherein
the first low charge quantity region is in contact with the plurality of electric field relaxation regions from below.

4. The switching element according to claim 2, wherein
the n-type charge quantity in the first low charge quantity region is at least 0.4 times and at most 0.9 times the n-type charge quantity in the high charge quantity region.

5. The switching element according to claim 1, wherein
the plurality of electric field relaxation regions and the plurality of super junction p-type regions are connected through connection portions,
the connection portions have a p-type impurity concentration that is higher than a p-type impurity concentration in the plurality of electric field relaxation regions disposed above the connection portions and higher than a p-type impurity concentration in the plurality of super junction p-type regions disposed below the connection portions.

6. The switching element according to claim 1, wherein
the low charge quantity region has an n-type impurity concentration lower than that in the high charge quantity region.

7. The switching element according to claim 6, wherein
the n-type impurity concentration in the low charge quantity region is at least 0.4 times and at most 0.9 times the n-type impurity concentration in the high charge quantity region.

8. A method for manufacturing a switching element, the method comprising:
forming a super junction structure including a plurality of super junction n-type regions and a plurality of super junction p-type regions in a semiconductor substrate, so that the plurality of super junction p-type regions are disposed at intervals in a first direction in a substrate plane and extend in a second direction intersecting with the first direction in the substrate plane, the plurality of super junction n-type regions are disposed in spaces between the plurality of super junction p-type regions, each of the plurality of super junction n-type regions has a low charge quantity region at an upper end thereof and a high charge quantity region that is in contact with the low charge quantity region from below and has an n-type charge quantity higher than that in the low charge quantity region; and
forming, above the super junction structure, a plurality of electric field relaxation regions of a p-type, a plurality of n-type spacing regions, a plurality of trenches, a gate insulating film, a gate electrode, a source region of an n-type, and a body region of a p-type, so that the plurality of electric field relaxation regions linearly extend in the first direction and disposed at intervals in the second direction, the plurality of n-type spacing regions are disposed in spaces between the plurality of electric field relaxation regions, the plurality of electric field relaxation regions and the plurality of n-type spacing regions are in contact with the plurality of super junction p-type regions and the plurality of super junction n-type regions at lower ends thereof, the plurality of trenches are formed on an upper surface of the semiconductor substrate, each of the electric field relaxation regions has at least a portion located lower than the trenches, the gate insulating film and the gate electrode are disposed inside each of the plurality of trenches, the source region is disposed in a space between the plurality of trenches and is in contact with the gate insulating film, and the body region is disposed in the space between the plurality of trenches and is in contact with the gate insulating film below the source region.
